(19) United States
(12) Patent Application Publication
(10) Pub. No.: US 2013/0269428 A1
(43) Pub. Date: Oct. 17, 2013

(54) Measurement Transducer of a Thermal Mass Flow Meter for Determining the Flow of a Medium through a Pipe and Method for Fabricating it

(71) Applicants: Tobias Baur, Reinach (CH); Fanos Christodoulou, Nicosia (CY); Axel Pfau, Aesch (CH); Martin Barth, Basel (CH); Arno Lang, Mullheim (DE)

(72) Inventors: Tobias Baur, Reinach (CH); Fanos Christodoulou, Nicosia (CY); Axel Pfau, Aesch (CH); Martin Barth, Basel (CH); Arno Lang, Mullheim (DE)

(73) Assignee: Endress + Hauser Flowtec AG, Reinach (CH)

(21) Appl. No.: 13/808,305

(22) PCT Filed: Jun. 20, 2011
(86) PCT No.: PCT/EP11/60205

§ 371 Date: Jun. 17, 2013

(30) Foreign Application Priority Data
Jul. 8, 2010 (DE) 102010031127.8

(51) Int. Cl. G01F 1/692; H01L 29/40

(52) U.S. Cl. CPC G01F 1/692; H01L 29/401
USPC 73/204.26; 29/595

(57) ABSTRACT

A measurement transducer of a thermal mass flow meter for determining the flow rate of a medium that flows through a pipe, which comprises at least one thin film resistance thermometer, which is arranged in a sheath, wherein the sheath comprises a first open end, out of which at least one cable for electrical contact with the resistance thermometer is led out of the sheath, wherein the cable in the sheath is embedded in a first fill material, at least in sections, and wherein the thin film resistance thermometer is at least partially covered by a second fill material, which is a gaseous, liquid, semi-liquid, powder or solid and in the case cited last, comprises a hardness of at most Shore A 90, and that the first fill material comprises a hardness of at most Shore D 98.

The present invention relates to a measurement transducer of a thermal mass flow meter for determining the flow of a medium through a pipe and a method for fabricating it, wherein the measurement transducer comprises at least one thin film resistance thermometer, which is arranged in a sheath, wherein the sheath comprises a first end, out of which at least one cable for electrically contacting the thin film resistance thermometer is led out of the sheath, wherein the cable in the sheath is embedded in a fill material, at least in sections.

Conventional thermal mass flow meters normally use two temperature sensors that are embodied as identically as possible, which are arranged in metal sheaths, mostly pin-shaped, so-called stingers or prongs, and which are in thermal contact with the medium that flows through the pipe or through a measurement tube; mostly they are submerged in the medium. For industrial application, both temperature sensors are usually built into a measurement tube; the temperature sensors can however also be directly mounted into the pipe. One of the two sensors is a so-called active temperature sensor, which is heated by means of a heating unit. Either an additional resistance heater is provided as a heating unit, or the temperature sensor is itself a resistive element, e.g. it is a RTD-(Resistance Temperature Device) Sensor that is warmed through the conversion of electrical power, e.g. through an appropriate variation of the measurement current. The second temperature sensor is a so-called passive temperature sensor: it measures the temperature of the medium.

Usually, in a thermal mass flow meter, the heatable temperature sensor is heated so that a constant temperature difference is maintained between the two temperature sensors. Alternatively, it has also become known to supply a constant heating power via a regulator unit.

If there is no flow in the measurement tube, then a quantity of heat that is constant in time is required to maintain the predetermined temperature difference. On the contrary, if the medium that is to be measured is moving, the cooling off of the heated temperature sensor is essentially dependent on the mass flow rate of the medium flowing past. Given that the medium is colder than the heated temperature sensor, heat is transported away from the heated temperature sensor by the medium. So in order to maintain the set temperature difference between the two temperature sensors in a flowing medium, an increased heating power is required for the heated temperature sensor. The increased heating power is proportional to the mass flow rate and the mass flow of the medium through the pipe, respectively.

On the contrary, if a constant heating power is supplied, then the temperature difference between the two temperature sensors decreases in response to the flow of the medium. The respective temperature difference is then proportional to the mass flow rate of the medium through the pipe and measurement tube, respectively.

Hence, a functional relationship arises between the heating energy required to heat the temperature sensor and the mass flow rate through a pipe and through a measurement tube, respectively. The dependence of the so-called heat transfer coefficient on the mass flow rate of the medium through the measurement tube and pipe, respectively, is used in thermal mass flow meters for determining the mass flow rate. Devices that are based on this principle are proffered by the applicant under the designation ‘t-switch’, ‘t-trend’ or ‘t-mass’.

To date, RID-elements have mainly been implemented with platinum wire coiled in a helical-shape in thermal mass flow meters. In thin film resistance thermometers (TFRTDs), conventionally, a meandering shaped platinum layer is coated onto a substrate by vapor deposition. A glass layer is then applied on top of this for protecting the platinum layer. The cross section of the thin film resistance thermometer is, in contrast to RTD-elements that comprise rounded cross sections, rectangular. The heat transfer in the resistance element and/or out of the resistance element occurs after this via two surfaces resting opposite to each other, which together make up a large portion of the total surface area of a thin film resistance thermometer.

The fixture of a cuboid shaped thin film resistance thermometer in a rounded pin-shaped sheath is solved in the following way in U.S. Pat. No. 6,971,274 and U.S. Pat. No. 7,197,953. In a metal spacer with a rectangular cavity, the thin film resistance thermometer is positioned so that at least the two large surfaces of the thin film resistance thermometer that are on opposing sides make virtually seamless contact with the surfaces of the spacer that are opposite to them. For this, the spacer comprises a rectangular cavity, which is manufactured to correspond to the external dimensions of the thin film resistance thermometer. The spacer is to tightly hold the thin film resistance thermometer. For this, the spacer and the thin film resistance thermometer form an interference fit as it were. The spacer and the pin-shaped sheath also form an interference fit. The implementation of a molding compound or another sort of fill material is therefore superfluous. The advantage of this construction consists of a good all-around heat coupling between the thin film resistance thermometer and the measurement medium through the spacer. However, due to the tight seating of the thin film resistance thermometer and/or the different thermal expansion coefficients of the materials involved, mechanical tension arises in the thin film resistance thermometer.

One such measurement transducer is shown in the WO 2009/115452 A2. In addition, the German patent application with the Aktenzeichen (case/file number) 102009028850.3, which has not been disclosed at the point in time of this patent application, shows an improved process for fabricating a temperature sensor, in particular for a thermal mass flow meter, with at least one tubular pin-shaped sheath with a first open end and a second open end, where the first open end of the pin-shaped sheath is held in a sensor holder; furthermore with at least one resistance thermometer with a first surface and at least a second surface, which lies opposite the first surface, wherein a spacer with a resistance thermometer secured onto a first surface of the spacer is inserted into the second open end of the pin-shaped sheath and the second open end of the pin-shaped sheath is subsequently sealed with a plug.

The patent application publication WO 2009/146447 A1 discloses a temperature sensor in a sheath, embedded in a first fill material, and provided with cables, which are embedded in a second fill material.

The patent specification DE 10 2007 023 824 B4 discloses a thermal mass flow Meter with at least one heater element, which is mounted on a holder, where said holder is submerged in the medium. The holder thereby comprises two zones of differing thermal conductivity. The heating element is arranged in a short zone of low thermal conductivity. The connecting wires of the heating element are arranged, electrically isolated, in a long zone of greater thermal conductivity. The zone of low thermal conductivity is, by way of example, filled with air. The long zone of greater thermal conductivity is, in a preferable embodiment, formed by a pressed metal oxide. The problem of mechanical tension on the thin film resistance sensor and on the cables, in particular during temperature variations, is not more closely explained.

The DE 40 03 638 C2 also shows a similar construction, where the heating element in surrounded by air, but the remaining space inside the sheath is filled up with molding resin composition.

The patent specification DE 10 2006 034 246 B3 discloses then a thermo couple for a resistance thermometer. A measurement resistance is covered by a ceramic or mineral based fill material. At least one connecting wire, however, is not covered by fill material. An expansion compensation mechanism is provided to adjust for temperature caused mechanical tensions—the wires comprise a bend. The temperature caused mechanical tensions arise due to different thermal expansion coefficients of the materials being used and through deployment of the sensor in an exhaust line of combustion engines, wherein up to 1000° C. can prevail.

The object of the invention consists in proposing a thermal mass flow meter that is robust in the face of temperature changes.

The object will be achieved by means of the subject matter of the independent claim 1 and by means of the subject matter of the independent claim 11. Further embodiments of the invention are found in the features of the respective dependent claims.

A measurement transducer, according to the invention, of a thermal mass flow meter, in particular for industrial process technology, for determining the flow rate of a medium that flows through a pipe, comprises at least one, in particular exactly one, heatable or non-heatable thin film resistance thermometer. This is arranged in a one sided, sealed off sheath, wherein the sheath comprises a first open end, out of which at least one cable for electrical contact with the resistance thermometer is lead out of the sheath. This first open end is fastened in a sensor holder of the thermal mass flow meter, by way of example. Normally, two or more cables are provided for contacting the thin film resistance thermometer. The cables in the sheath are embedded in a first fill material, at least in sections. The thin film resistance thermometer is at least partially covered by a second fill material in the sheath. The second fill material is thereby a gas or a gas mixture, air by way of example, or it is a fluid, indeed a highly viscous, and thereby semi-liquid, fluid or gel, or the second fill material consists of a loose powder or it is solid at 1013 mBar and 20° C., by way of example also a pressed powder, where said second fill material then comprises a hardness of at most Shore A 90, in particular at most Shore A 70. The first fill material is also either semi-liquid or solid and comprises then a hardness of at most Shore A 98, in particular at most Shore A 70. Further fill materials are formed by means of normal molding compounds or epoxy resin compositions. These are semi-liquid during the fabrication and harden to a solid.

According to a first embodiment of the invention, the first and second fill materials are not identical. In particular, the second fill material is softer than the second fill material.

A thermal mass flow meter according to the invention comprises at least one measurement transducer according to the invention. Thermal mass flow meters according to the invention are used first and foremost in process industry. It is then an industrial process measurement technology device. The operational requirements of such devices comply with the process requirements. Usual temperature ranges of processes in industrial process technology are between 50° C. and 350° C., with pressures up to 200 Bar.

According to one embodiment, the first fill material as well as the second fill material is solid at 1013 mBar and 20° C. and third fill material, in particular a gas or gas mixture, air for example, is enclosed in the sheath between the first fill material and the second fill material. Furthermore, the third fill material could however again conceivably be a liquid, semi-liquid or solid material. An example of a semi-liquid material is Sielgel (trade name). Pressed powders as well by way of example, such as pressed metal oxide for example, comprise a solid aggregate state, even if they comprise a certain level of porosity.

If a gas or gas mixture, as a third fill material, is enclosed in the sheath between the first fill material and the second material, then it is implied that the sheath is sealed, in particular hermetically sealed, on a first end by the first fill material.

Epoxy molding resin composition, by way of example, such as the epoxy resin composition Durapont 868 proffered by Cotronics, is an alternative to air for a second fill material, to cite an example. The first fill material is, by way of example, an epoxy molding resin composition with the product name Durapot 861 or Stycast 2850.

In an embodiment, the first fill material comprises a thermal expansion coefficient of at most 10*10⁻⁵ K⁻¹ (linear), in particular of at most 3.8*10⁻⁵ K⁻¹ (linear). The second fill material is then either gaseous, liquid or semi-liquid, or it likewise comprises a thermal expansion coefficient of at most 1010⁻⁵ K⁻¹ (linear), in particular of at most 3.8*10⁻⁵ K⁻¹ (linear). A usual silicon filling comprises, for example, a thermal conductivity of ca. 0.2 W/(m*K). If a third fill material is provided between the first and second fill materials, then its thermal expansion coefficient amounts to at most 30*10⁻⁵ K⁻¹ (linear). The sheath is conventionally composed of a stainless steel, e.g. a nickel alloy. The thermal conductivity of 360L stainless steel (equivalent to the European steel number 1.4404 or grade: X2CrNiMo 17-12-3) is about 15 W/(m*K) and the thermal expansion coefficient α is ca. (13 to 18)*10⁻⁶ K⁻¹. In comparison, the thermal conductivity of pure copper is ca. 400 W/(m*K), which is used, by way of example, as a spacer between sheath and thin film resistance thermometer.

The cables for contacting the thin film resistance thermometer are connected to the thin film resistance thermometer at at least one point, e.g. by bonding. The length of each individual cable, between the point of the connection of the cable with the thin film resistance thermometer and the first end of the sheath is thereby substantially longer than the distance between the point of the connection of the cable with the thin film resistance thermometer and the first end of the sheath. The length amounts to in particular at least 105%, in particular at least 107%, and even at least 110% of the distance between the point of the connection of the cable with the thin film resistance thermometer and the first end of the sheath. The cable, by way of example, is bent or coiled in a predetermined section. An expansion compensation mechanism is formed in this way. A tensile force applied to the cable in the region of the first end of the sheath, or outside of the sheath, is not directly transferred to the thin film resistance thermometer given that the bend or coil, in general the expansion compensation mechanism, is elastic and easily deformed so that the tensile force is not transferred in whole.

Additionally, this section is embedded, by way of example, in a gaseous, liquid or semi-liquid fill material. Either directly in the second fill material, or if the second fill material does not seem suitable for that, e.g. it is solid, in the third fill material, between the first and second fill materials.

The distance between the second fill material and the first fill material, that is, the extension of the third fill material along the longitudinal axis of the sheath, is then at least large enough so that the expansion compensation mechanism is to completely embedded, e.g. at least five times the inner diameter of the sheath. The cable thickness, in this example, then amounts to at most 1/10 of the inner diameter of the sheath.

In an embodiment, the thin film resistance measurement is attached to a spacer, which is arranged between the thin film resistance thermometer and sheath. The spacer is inserted into the sheath along with the thin film resistance thermometer that is attached to it, in particular through a second open end of the sheath, during the mounting of the measurement transducer. The sheath thereby comprises two open ends, a first and a second. The thin film resistance thermometer is inserted into the sheath through the second open end, wherein the cable that is connected to the thin film resistance thermometer is led out of the sheath through the first open end. After introducing the thin film resistance thermometer in the sheath, the second open end is sealed off with a stopper, by way of example. The stopper naturally protrudes at least partially into the second sheath. Alternatively, the sheath can be sealed with a cap. The stopper is, by way of example, welded to the sheath by means of a laser beam welding (LBW) process and hermetically seals it. In order to facilitate the insertion of the stopper, it can comprise a beveled edge.

The spacer is, by way of example, a cylindrically shaped body with a groove. For good thermal conduction, it is composed of e.g. copper and enters the sheath with an interference fit. The thin film resistance thermometer is, by way of example, soldered onto the spacer, in particular in the groove of the spacer.

The invention permits a multitude of embodiments. Some of these are to be more closely explained with the help of the following figures. In the figures, equivalent elements are provided with the same reference characters.

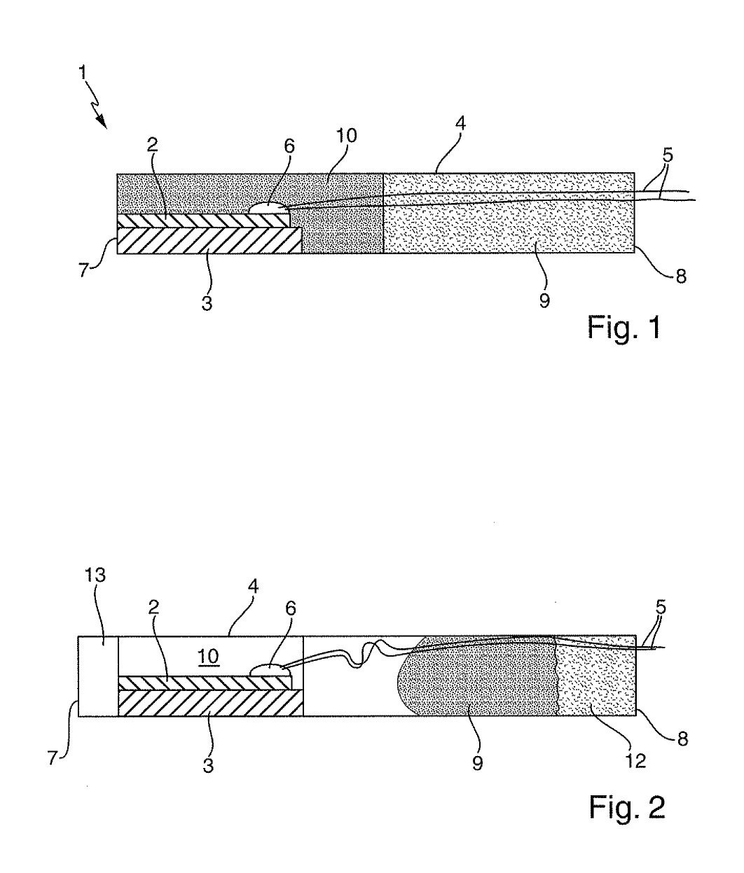

FIG. 1 shows a longitudinal section of a measurement transducer according to the invention in a first embodiment,

FIG. 2 shows a longitudinal section of a measurement transducer according to the invention in a second embodiment,

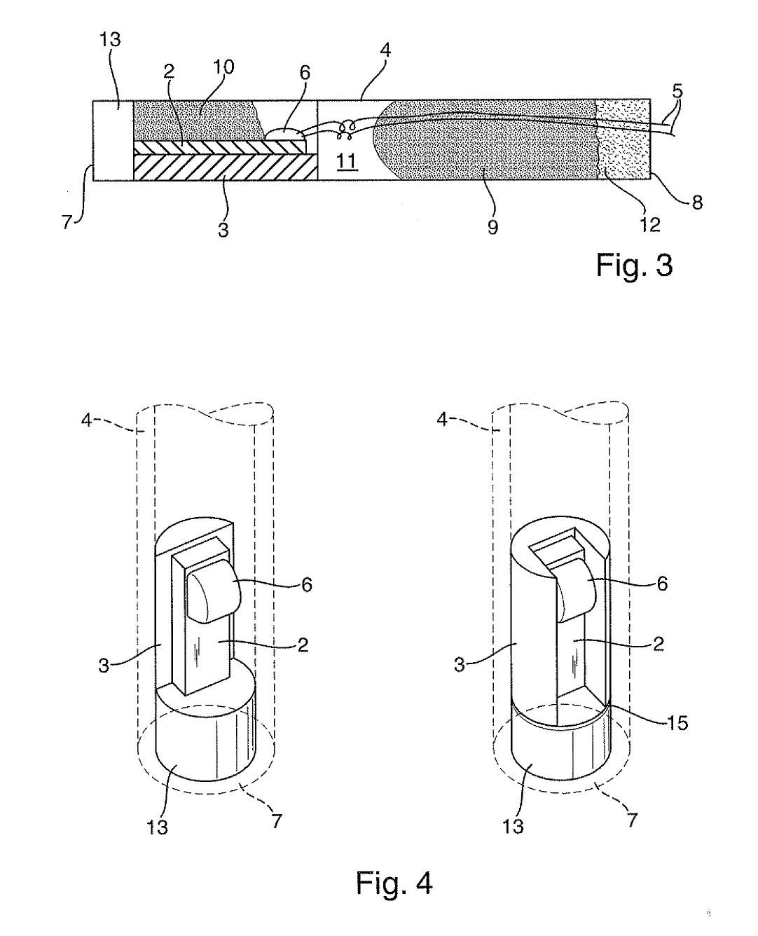

FIG. 3 shows a longitudinal section of a measurement transducer according to the invention in a third embodiment,

FIG. 4 shows a measurement transducer according to the invention in perspective, without fill material,

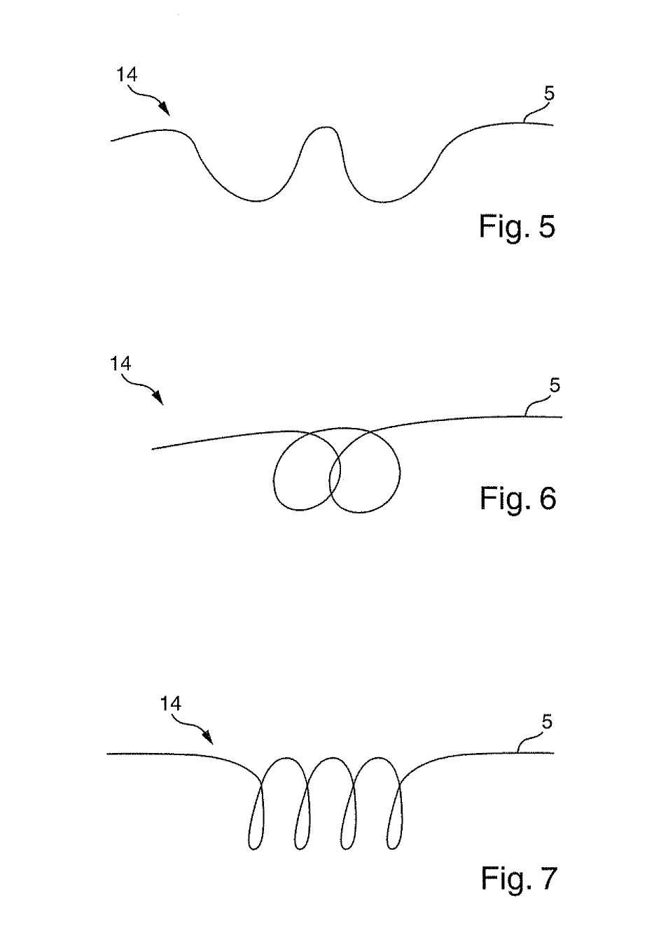

FIG. 5 shows a further embodiment of an expansion compensation mechanism,

FIG. 6 shows a further embodiment of an expansion compensation mechanism,

FIG. 7 shows a further embodiment of an expansion compensation mechanism.

In FIG. 1, a longitudinal section of a measurement transducer 1 according to the invention is depicted. The measurement transducer 1 is embodied for use in a thermal mass flow meter, for determining the mass flow rate of a medium that flows through a pipe. A thin film resistance thermometer (TFRTD) 2 is arranged on a spacer 3 in a sheath 4. The spacer 3 is found between the sheath 4 and the thin film resistance thermometer 2. It preferably consists of a material that is a good heat conductor, such as copper for example. The thin film resistance thermometer 2 is soldered onto the spacer 3 in this example. On the side of the thin film resistance s thermometer 2 facing away from the spacer 3, cables 5 for electrical contact with the thin film resistance thermometer 2 are connected to the thin film resistance thermometer 2 at a point 6. The connection of the cables 5 with the thin film resistance thermometer 2 is fabricated, by way of example, by welding. Here, the connection of the cables 5 with the thin film resistance thermometer 2 is depicted by a drop of sealant caulk 6. The connection of the cables 5 with the thin film resistance thermometer 2 is also designated as bonding. The side of the thin film resistance thermometer 2 with the drop of sealant caulk 6 is covered by a second fill material 10, here a molding compound, such as epoxy resin composition, by way of example, such as Durapont 868, with a hardness of Shore A 85.

The sheath 4 comprises a first end 8, here open, out of which the cables 5 are led out of the sheath 4 and a second end 7, here closed. The sheath comprises, by way of example, the form of a test tube. The second fill material 10 completely fills the sheath in the region of its second end 7. However, not the entire sheath 4 is filled up with the second fill material 10. In the region of the first end 8 of the sheath 4, the sheath 4 is filled with a first fill material 9. The cables 5 are embedded in this first fill material 9. Here, the first fill material 9 consists of, by way of example, Durapot 861 with a hardness of Shore D80.

FIG. 2 shows a further longitudinal section of a measurement transducer 1 according to the invention, with a thin film resistance thermometer 2 arranged in a sheath 4. Here as well, the sheath 4 comprises a first, open end 8 out of which cables 5 for electrical contact with the thin film resistance thermometer 2 are led out of the sheath 4, and a second end 7. The second end of the sheath 4 is closed with a stopper 13. The sheath 4 thus comprises two open ends 7 and 8, wherein the second, initially open, end 7 is sealed by a stopper 13, in particular after the thin film resistance thermometer 2 has been inserted into the sheath 4 through the initially open second end 7 of the sheath 4.

Cables 5 are first bent, coiled or spiraled in a predetermined region, or section respectively, of the cables 5 in accordance with predetermined ways and means, so that an expansion compensation mechanism is produced and the cables can elastically yield to a force. The cables 5 are subsequently fastened to the thin film resistance thermometer 2; they are welded or soldered on, by way of example. The soldering area is very small and is designated here for the sake of simplicity as a soldering point and is depicted together with the sealant caulk 6. The thin film resistance thermometer 2 is subsequently soldered onto a spacer 3 and is inserted together with this into the sheath 4 through the second open end 7, or it is inserted directly into the sheath 4 through the second open end 7, wherein the cables 5 are led out of the sheath 4 through the first open end 8 of the sheath. Subsequently, the second open end 7 of the sheath 4 can be sealed with a stopper 13 and a first fill material 9 is filled into the sheath 4 through the first open end 8 of the sheath 4, so that the thin film resistance thermometer 2 is covered by a second fill material 10, in this case air, and the cables 5 are in large part embedded in the first fill material 9, wherein the cables 5 in the region of the expansion compensation mechanism, i.e. in the bent section in this embodiment, are not embedded in the first fill material 9. In this example, this section is surrounded by the second fill material 10. Further embodiments of expansion compensation mechanisms are depicted in FIGS. 5-7.

Alternatively, depending on the embodiment of the spacer 3, the thin film resistance thermometer 2 is molded with a molding compound before the insertion of the spacer 3 into the sheath. The spacer 3 is here embodied as a spacer with a groove, which is already known from the prior art according to WO 2009/115452 A2. The spacer forms an interference fit with the sheath 4. The stopper 13 protrudes into the sheath 4. While inserting the stopper 13, the spacer 3 can also be inserted into the housing 4. In this embodiment, no further fastening of the thin film resistance thermometer 2 in the sheath 4 is necessary. If the thin film resistance thermometer 2 is inserted into the sheath 4 without a spacer 3, then it can be fastened in the sheath 4 without an additional fastening step while bringing in the second fill material 10, a molding process, by way of example. If the second fill material 10 consists of a gas or is gel like or honey-like, then the thin film resistance thermometer 2 can be fastened to the sheath before bringing in the second fill material 10, by bonding or soldering for example.

As has already been described, the amount of the first fill material 9 is measured so that the thin film resistance thermometer 2 and the bent section 14 or the coiled spool shaped section or the coiled helix shaped section of the cables 5 are not covered with or embedded in the first fill material 9. In this embodiment, the measurement transducer 1 in the sheath 4 further comprises a fourth fill material 12, which is filled in through the open first end 8 of the sheath 4 after the infilling of the first fill material 9.

In FIG. 3 a further measurement transducer 1 according to the invention is visualized.

In the sheath 4, a thin film resistance thermometer 2 is brought in, which is covered by a second fill material 10. This second fill material comprises a hardness of less than Shore A 90. Looking further, from the second end 7 of the sheath 4 outwards to the first end 8 of the sheath 4, a third fill material 11 follows, wherein the expansion compensation mechanisms 14 of the cables 5 are embedded. The third fill material 11 consists, according to the invention, of a gas or a gas mixture, is fluid or highly viscous. A “Sielgel” (gel trade name) is used here. The third fill material 11 is surrounded by the sheath 4 and the first fill material 9 and the second fill material 10. After the first fill material 9, wherein the cables are in large part embedded, yet a fourth fill material 12 follows, which seals the first open end 8 of the sheath.

Such a measurement transducer 1 is fabricated, by way of example, in the following way. The thin film resistance thermometer 2 is soldered to the spacer 3 and subsequently molded with the second fill material 10. After inserting the spacer 3 in the sheath 4 and at the same time leading the cables 5 out of the sheath 4 out of its open end 8, the third fill material 11 is filled into the sheath, and afterwards the first fill material 9 and finally the fourth fill material 12.

Alternatively, the spacer 3 and soldered-on thin film resistance thermometer 2 are inserted into the sheath through its open second end 7 and thereafter covered with second fill material 10. Whether this through the second open end 7 or first open end 8 of the sheath 4, then with closed or open second end 7 of the sheath 4, depends on the respective fill material. Preferably, the sequence is to first solder the thin film resistance thermometer 2 on the spacer 3, then fabricate the expansion compensation mechanism 14 of the cables, bring the spacer 3 together with the thin film resistance thermometer 2 and the cables 5 into the sheath and to seal the second open end 7 of the sheath 4 with a stopper. Subsequently, the first, second, third and as the case may be, fourth fill materials are brought in through the first open end 8 of the sheath 4.

This occurs, by way of example, by means of a dosing nozzle, which is inserted into the sheath 4 and through which the respective fill material is brought-in. The nozzle is positioned in the sheath according to the fill material and is removed from the sheath during the filling process in the direction of the first open end of the sheath at the same speed with which the sheath is being filled. The viscosity of the respective fill material, influenced by cohesion forces, predominantly determines the flow behavior of a molding resin composition, such as Durapont 861 for example, which cures at room temperature. In selecting the conditions for the filling operation of the sheath, such as for example the temperature of the fill material, the temperature of the sheath or ambient pressure and the filling angle of the sheath, the fill material can be positioned at a predetermined place.

The amounts of the fill materials, in particular of the first fill material 9 and/or the second fill material 10 are measured, with prevailing production requirements taken into account, so that the thin film resistance thermometer 2 is at least partially covered by the second fill material 10 and as the case may be, so that the extension of the third fill material 11 along the longitudinal axis of the sheath 4 amounts to at least 5 times the inner diameter of the of the sheath 4, wherein the section of the cables 5 with the bent, coiled or spiraled cables 5 is embedded in the third fill material 11.

Further intermediate steps for fastening the thin film resistance thermometer 2 on the spacer 3, for fabricating the spacer 3 or the stopper 13 or for sealing the second open end 7 of the sheath 4 are known to a person skilled in the art from DE 10 2009 028 850.3.

The measurement transducer 1 according to the invention in FIG. 4 comprises a spacer between sheath 4 and thin film resistance thermometer 2. In this view, no fill materials are depicted. The stopper 13 comprises a beveled edge 15 in order to insert it chip-free into the sheath 4. The cables 5 are bonded to the thin film resistance thermometer via a soldering or welding point, which is covered with sealant caulk 6.

In the FIGS. 5 to 7, further possible expansion compensation mechanisms 14 are sketched. The cables 5 are bent, coiled, folded, wrapped around, twisted or spiraled in the section of the region of the third fill material 11, wherein they are likewise embedded. In FIG. 5 they are doubly bent to a ω, in FIG. 6 they are coiled into two loops and in FIG. 7 they are spiraled into a helix with 4 windings.

### LIST OF REFERENCE CHARACTERS

1 Measurement Transducer

2 Thin film Resistance Thermometer

3 Spacer

4 Sheath

5 Cables

6 Sealant Caulk (Bonding)

7 Second End of the Sheath

8 First End of the Sheath

9 First Fill Material

10 Second Fill Material

11 Third Fill Material

12 Fourth Fill Material

13 Stopper

14 Expansion Compensation Mechanism of the Cables

15 Beveled Edge

1-15. (canceled)

16. A measurement transducer of a thermal mass flow meter for determining the flow rate of a medium that flows through a pipe, which comprises:
a sheath;
at least one thin film resistance thermometer, which is arranged in a said sheath, wherein said sheath includes a first open end, out of which at least one cable for electrical contact with said thin film resistance thermometer is led out of said sheath, wherein:
said at least one cable in said sheath is embedded in a first fill material, at least in sections; and
said thin film resistance thermometer is at least partially covered by a second fill material, which is gaseous, liquid, semi-liquid, powder or solid and in the case cited last, comprises a hardness of at most Shore A 90, and that the first fill material comprises a hardness of at most Shore D 98.

17. The measurement transducer according to claim 16, wherein:
the second fill material is air.

18. The measurement transducer according to claim 16, wherein:
the first fill material and the second fill material are solid at 20° C. and 1013 mBar; and
a third fill material is enclosed in said sheath between the first fill material and the second fill material.

19. The measurement transducer according to claim 16, wherein:
the first fill material is a molding resin composition, in particular epoxy resin composition.

20. The measurement transducer according to claim 16, wherein:
said at least one cable is connected to said thin film resistance thermometer at at least one point; and
said at least one cable, between the point of the connection of said at least one cable with said thin film resistance thermometer and the first end of said sheath comprises a length substantially greater, in particular at least 7% greater, than the distance between the point of the connection of said at least one cable with said thin film resistance thermometer and the first end of said sheath.

21. The measurement transducer according to claim 16, wherein:
said at least one cable in a region of the second fill material or in the region of the third fill material comprises at least one of:
a bent section, at least one coiled spool shaped section and at least one coiled helix shaped section.

22. The measurement transducer according to claim 18, the expansion of the third fill material along the longitudinal axis of the sheath amounts to at least five times the inner diameter of the sheath, wherein the cable thickness amounts to at most 1/10 of the inner diameter of the sheath.

23. The measurement transducer according to claim 16, further comprising:
a spacer, wherein:
said thin film resistance thermometer is attached to said spacer, which is arranged between said thin film resistance thermometer and said sheath.

24. The measurement transducer according to claim 16, wherein:
the second end of said sheath is sealed by means of a stopper.

25. The measurement transducer according to claim 16, wherein:
said sheath is pin-shaped;
a fourth fill material fills the said sheath between the first fill material and the first end of said pin-shaped sheath.

26. Process for fabricating a measurement transducer, comprising:
a sheath; at least one thin film resistance thermometer, which is arranged in a said sheath, wherein said sheath includes a first open end, out of which at least one cable for electrical contact with said thin film resistance thermometer is led out of said sheath, wherein: said at least one cable in said sheath is embedded in a first fill material, at least in sections; and said thin film resistance thermometer is at least partially covered by a second fill material, which is gaseous, liquid, semi-liquid, powder or solid and in the case cited last, comprises a hardness of at most Shore A 90, and that the first fill material comprises a hardness of at most Shore D 98, wherein the second end of the sheath is open, the method comprises the step of:
bending, coiling or spiraling of the cable in a predetermined section of the cable;
fastening the cable, for electrical contact with the thin film resistance thermometer, to the thin film resistance thermometer;
inserting the thin film resistance thermometer into the sheath through the second open end of the sheath, wherein the cable is led out of the sheath through the first open end of the sheath; and
bringing in the first fill material through the first open end of the sheath.

27. The process for fabricating a measurement transducer according to claim 26, wherein:
the thin film resistance thermometer is attached to the spacer before bringing the thin film resistance thermometer into the sheath;
the spacer with the thin film resistance thermometer is inserted into the sheath, and
after inserting the thin film resistance thermometer into the sheath, the second open end is sealed with a stopper.

28. The process for fabricating a measurement transducer according to claim 27, wherein:
the spacer comprises an essentially cylindrical form and a groove parallel to a longitudinal axis of the spacer, where the thin film resistance thermometer is attached in said groove; and
after attaching the thin film resistance thermometer to the spacer and before inserting the thin film resistance thermometer into the sheath, the groove of the spacer is filled with the second fill material so that the thin film resistance thermometer is at least partially covered by the second fill material.

29. The process for fabricating a measurement transducer according to claim 26, wherein:
the second fill material is brought in through the second open end of the sheath after inserting the film resistance thermometer into the sheath.

30. The process for fabricating a measurement transducer according to claim 26, wherein:
the amount of the second material is measured so that the thin film resistance thermometer is at least partially covered by the second fill material; and
in the amount of the third fill material is measured so that the expansion of the third fill material along the longitudinal axis of the sheath amounts to at least five times the inner diameter of the sheath.
